(19) United States
(12) Patent Application Publication
(10) Pub. No.: US 2024/0297497 A1
(43) Pub. Date: Sep. 5, 2024

(54) CONTROL METHOD OF BATTERY SYSTEM, AND BATTERY CONTROL DEVICE AND BATTERY SYSTEM PERFORMING THE SAME

(71) Applicant: SAMSUNG SDI CO., LTD., Yongin-si (KR)

(72) Inventors: Duckgu CHO, Yongin-si (KR); Younghwan EUM, Yongin-si (KR); Daehun LEE, Yongin-si (KR)

(21) Appl. No.: 18/487,873

(22) Filed: Oct. 16, 2023

(30) Foreign Application Priority Data
Mar. 3, 2023 (KR) 10-2023-0028668

(51) Int. Cl. H02H 7/18; H01M 10/42; H02J 7/00

(52) U.S. Cl. CPC H02H 7/18; H01M 10/425; H02J 7/007182; H01M 2010/4271; H01M 2010/4278

(57) ABSTRACT

A battery control device of a battery system including at least one battery, includes: a storage device to store a safety limit range for a parameter related to a state of the at least one battery, and a threshold setting value for the parameter; a communication device to communicate with a test device; and a controller to: operate a protection function of the battery system based on the threshold setting value; change the threshold setting value based on a change value received from the test device if a change of the threshold setting value is requested; and limit the change of the threshold setting value if the change value is out of the safety limit range.

### CROSS-REFERENCE TO RELATED APPLICATION(S)

This application claims priority to and the benefit of Korean Patent Application No. 10-2023-0028668, filed on Mar. 3, 2023, in the Korean Intellectual Property Office, the entire content of which is incorporated by reference herein.

### BACKGROUND

### 1. Field

Aspects of embodiments of the present disclosure relate to a control method of a battery system, and a battery control device and a battery system for performing the same.

### 2. Description of Related Art

An energy storage system (ESS) is a system that increases energy utilization efficiency by storing a significant amount of electrical energy, and then supplying the stored electrical energy when the electrical energy is needed.

Typically, the ESS may include: a battery system; a battery management system (BMS) that manages the battery system, such as monitoring a voltage, a current, a temperature, and/or the like of the battery system; a power conversion system (PCS) that performs alternating current (AC)-direct current (DC) conversion and power distribution functions; and an energy management system (EMS) that integrates and controls the entire system of the ESS, such as controlling the energy flow of the ESS, and collecting and managing information about a state of the ESS. In addition, the battery system may include a plurality of battery racks that are electrically connected to each other. Each battery rack may include a plurality of battery modules that are electrically connected to each other, and each battery module may include a plurality of cells that are electrically connected to each other.

The above information disclosed in this Background section is for enhancement of understanding of the background of the present disclosure, and therefore, it may contain information that does not constitute prior art.

### SUMMARY

Generally, a test operation is conducted to check whether or not the ESS operates normally before the ESS is applied to the field. During the test operation, a test is conducted to check whether or not a protection function of the battery system works normally. During the test of the battery system, a worker arbitrarily changes threshold values of parameters (e.g., a voltage, a current, a temperature, and/or the like) that are used to determine whether or not a protection function operates in order to prevent or substantially prevent damage to the battery system, and then proceeds with the test. In this process, when the threshold values are incorrectly adjusted due to a worker's error and/or the like, safety problems, such as damage to the battery system, may occur when the protection function does not operate, despite an actual problem occurring in the battery system during the test.

Embodiments of the present disclosure are directed to a control method of a battery system that may prevent or substantially prevent safety problems due to an incorrect threshold value adjustment during battery system testing from occurring, and a battery control device and a battery system for performing the same.

According to one or more embodiments of the present disclosure, a battery control device of a battery system including at least one battery, includes: a storage device configured to store a safety limit range for a parameter related to a state of the at least one battery, and a threshold setting value for the parameter; a communication device configured to communicate with a test device; and a controller configured to: operate a protection function of the battery system based on the threshold setting value; change the threshold setting value based on a change value received from the test device if a change of the threshold setting value is requested; and limit the change of the threshold setting value if the change value is out of the safety limit range.

In an embodiment, to limit the change of the threshold setting value, the controller may be configured to maintain the threshold setting value as a previous value if the change value is out of the safety limit range.

In an embodiment, to limit the change of the threshold setting value, the controller may be configured to change the threshold setting value to a value corresponding to the safety limit range if the change value is out of the safety limit range.

In an embodiment, the controller may be further configured to notify the test device that the change value is not a valid value if the change value is out of the safety limit range.

In an embodiment, the controller may be further configured to: change an operation mode of the battery system to a test mode when requested to enter the test mode by the test device; and allow the threshold setting value to be changed only while the battery system operates in the test mode.

In an embodiment, if the threshold setting value is changed while the battery system operates in the test mode, the controller may be further configured to control an operation of the protection function based on the changed threshold setting value.

In an embodiment, the controller may be further configured to change an operation mode of the battery system to a normal mode if connection between the battery system and the test device is disconnected, or if a termination of the test mode is requested by the test device.

In an embodiment, the controller may be further configured to change the threshold setting value to a default value if the operation mode of the battery system is changed to the normal mode, and the default value may be a value outside the safety limit range.

In an embodiment, the parameter may be a cell voltage, a module voltage, a current, or a temperature of the at least one battery, and the threshold setting value may be an overvoltage threshold value, a low voltage threshold value, an overcurrent threshold value, or an overtemperature threshold value of the at least one battery.

In an embodiment, the threshold setting value may be the overvoltage threshold value, and the default value of the overvoltage threshold value may be higher than an upper voltage limit of the safety limit range.

In an embodiment, the threshold setting value may be the low voltage threshold value, and the default value of the low voltage threshold value may be lower than a lower voltage limit of the safety limit range.

In an embodiment, the threshold setting value may be the overcurrent threshold value, and the default value of the overcurrent threshold value may be higher than an upper current limit of the safety limit range.

In an embodiment, the threshold setting value may be the overtemperature threshold value, and the default value of the overtemperature threshold value may be higher than an upper temperature limit of the safety limit range.

In an embodiment, the protection function may include a function of opening a switch connected between the at least one battery and a load of the battery system.

In an embodiment, the battery system may include: the at least one battery; and the battery control device.

According to one or more embodiments of the present disclosure, a control method of a battery system including at least one battery, includes: receiving a change request for a threshold setting value of a parameter related to a state of the at least one battery; determining whether or not a change value of the threshold setting value is out of a safety limit range; if the change value is within the safety limit range, changing the threshold setting value to the change value; if the change value is out of the safety limit range, limiting a change of the threshold setting value; and controlling an operation of a protection function of the battery system based on the threshold setting value.

In an embodiment, the limiting of the change of the threshold setting value may include: maintaining the threshold setting value as a previous value if the change value is out of the safety limit range; or changing the threshold setting value to a value corresponding to the safety limit range if the change value is out of the safety limit range.

In an embodiment, the method may further include: receiving a change request to a test mode; and changing an operation mode of the battery system to the test mode. The change of the threshold setting value may be allowed only while the battery system operates in the test mode.

In an embodiment, the method may further include: changing an operation mode of the battery system to a normal mode if a connection between the battery system and a test device is disconnected, or if termination of a test mode is requested; and changing the threshold setting value to a default value if the operation mode of the battery system is changed to the normal mode, the default value being a value outside the safety limit range.

In an embodiment, the parameter may be at least one of a cell voltage, a module voltage, a current, or a temperature of the at least one battery; the threshold setting value may be at least one of an overvoltage threshold value, a low voltage threshold value, an overcurrent threshold value, or an overtemperature threshold value of the at least one battery; the default value of the overvoltage threshold value may be higher than an upper voltage limit of the safety limit range; the default value of the low voltage threshold value may be lower than a lower voltage limit of the safety limit range; the default value of the overcurrent threshold value may be higher than an upper current limit of the safety limit range; and the default value of the overtemperature threshold value may be higher than an upper temperature limit of the safety limit range.

According to one or more embodiments of the present disclosure, safety problems due to incorrect threshold value adjustment during battery system testing may be prevented or substantially prevented from occurring.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 illustrates a schematic battery system according to an embodiment.

FIG. 2 illustrates a control method of a battery system according to an embodiment.

FIG. 3 illustrates an energy storage system including a battery system according to an embodiment.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

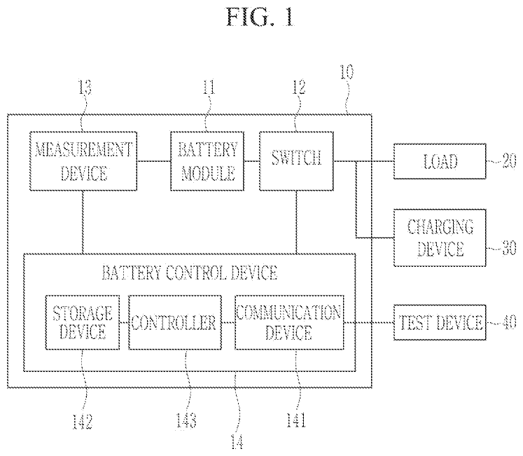

FIG. 1 illustrates a schematic battery system according to an embodiment.

Referring to FIG. 1, a battery system 10 according to an embodiment may include a battery module (e.g., a battery) 11, a switch 12, a measurement device 13, and a battery control device 14.

The battery module 11 may include a plurality of cells that are electrically connected to each other in series or in parallel.

The switch 12 is disposed between the battery module 11 and a load 20 and/or a charging device 30, and may electrically connect the battery module 11 and the load 20/the charging device 30 to each other, or may disconnect the electrical connection between the battery module 11 and the load 20/the charging device 30 from each other.

The measurement device 13 may measure parameters related to a state of the battery module 11, such as a voltage (e.g., a cell voltage, a module voltage, and/or the like), a current, and a temperature of the battery module 11. The measurement device 13 may include a voltage detection device, a current detection device, a temperature sensor, and the like.

The battery control device 14 may perform a protection function of the battery system 10 based on measured values related to the state of the battery module 11, and their threshold set values. The battery control device 14 may communicate with a test device 40 to determine whether or not to enter a test mode, and may change a threshold setting value within a suitable safety limit range (e.g., a preset or predetermined safety limit range) based on control information received from the test device 40 upon entering the test mode.

The battery control device 14 may include a communication device 141, a storage device 142, and a controller 143.

The communication device 141 may perform a communication function between the battery control device 14 and an external device. For example, the communication device 141 may communicate with the test device 40 via a controller area network (CAN) communication. In addition, for example, the communication device 141 may communicate with an upper controller via the CAN communication.

The storage device 142 may store information and data processed by the battery control device 14. For example, the storage device 142 may store a safety limit range of at least one parameter (e.g., a voltage, a current, a temperature, and/or the like) related to the state of the battery module 11. The safety limit range may indicate a range in which a change in the threshold setting value is allowed in the test mode of the battery system 10. In addition, for example, the storage device 142 may store a threshold setting value of at least one parameter related to the state of the battery module 11. The threshold setting value may indicate a value that is a criterion for determining whether or not to perform the protection function. The safety limit range may be a fixed value, and may not be changed after it is initially set. On the other hand, the threshold setting value may be a changeable value, and may be changed if the battery system 10 operates in the test mode.

The controller 143 may control the overall operations of the battery control device 14.

The controller 143 may obtain the measurement values of the parameters related to the state of the battery module 11, such as a voltage, a current, and a temperature, from the measurement device 13. The controller 143 may compare the obtained measurement value with a corresponding threshold setting value, and may determine whether or not to perform the protection function according to the comparison result. The protection function may include, for example, a function of opening the switch 12 to stop charging or discharging, a function of transmitting a warning message to an upper controller, and/or the like.

For example, the controller 143 may open the switch 12 to block charging or discharging of the battery module 11, if a module voltage or at least one cell voltage of the battery module 11 is greater than or equal to an overvoltage threshold or less than or equal to an undervoltage threshold. In addition, for example, the controller 143 may open the switch 12 to block charging or discharging of the battery module 11, if a charging/discharging current of the battery module 11 is equal to or greater than an overcurrent threshold. In addition, for example, the controller 143 may open the switch 12 to block charging or discharging of the battery module 11, if a temperature of the battery module 11 or at least one cell is equal to or higher than an overtemperature threshold.

The controller 143 may communicate with the test device 40 to determine an operation in the test mode. The controller 143 may enter the test mode if a test mode entry is requested by the test device 40. The controller 143 may terminate the test mode and may operate in a normal mode if the connection with the test device 40 is disconnected during operation in the test mode, or if termination of the test mode is requested by the test device 40.

After entering the test mode, the controller 143 may change the threshold setting value stored in the storage device 142 based on control information received from the test device 40. Before entering the test mode, the threshold setting value stored in the storage device 142 may be set to a default value. The controller 143 may receive a change value of the threshold setting value along with a change request of the threshold setting value from the test device 40, and may change the corresponding threshold setting value stored in the storage device 142 according to the received change value. If the change value received from the test device 40 is out of the safety limit range of the corresponding parameter, the controller 143 may stop changing the threshold setting value, and may notify the test device 40 that the change value is not a valid value. If the change value received from the test device 40 is out of the safety limit range of the corresponding parameter, the controller 143 may set the corresponding threshold setting value to a value corresponding to the safety limit range.

If the test mode ends, the controller 143 may return the changed threshold setting value to a default value. Here, the default value of each threshold setting value may be a value that is actually used to determine the operation of the protection function if the battery system 10 is actually used, and the safety limit range may be set to not deviate from the default value. For example, the default value of the overvoltage threshold value may be higher than an upper voltage limit defined by the safety limit range. In addition, for example, the default value of the low voltage threshold value may be lower than a lower voltage limit defined by the safety limit range. In addition, for example, the default value of the overcurrent threshold value may be higher than an upper current limit value defined by the safety limit range. In addition, for example, the default value of the overtemperature threshold value may be higher than an upper temperature limit defined by the safety limit range.

The controller 143 may include (e.g., may be configured as) a processor, such as a microprocessor, a microcontroller, a central processing unit (CPU), a processor core, a multiprocessor, an application-specific integrated circuit (ASIC), and/or a field programmable gate array (FPGA), having a physically structured circuit to perform functions expressed by codes or instructions included in a program.

The battery control device 14 described above may be integrated into a battery management system (BMS).

In FIG. 1, the battery system 10 including one battery module 11 and one switch 12 connected between the battery module 11 and the load 20/the charging device 30 is shown as an example, but the present disclosure is not limited thereto. According to another embodiment, the battery system 10 may include a plurality of battery modules (e.g., a plurality of batteries), or may include a plurality of switches between the battery module 11 and the load 20/the charging device 30.

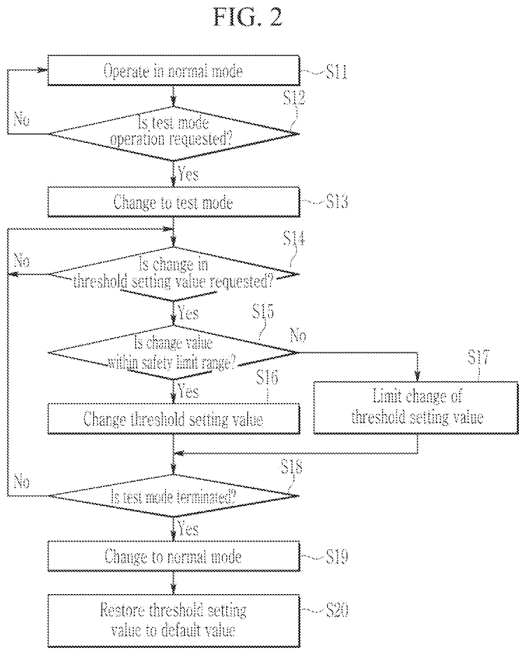

FIG. 2 illustrates a control method of a battery system according to an embodiment. The control method of FIG. 2 may be performed by the battery control device 14 illustrated in FIG. 1.

Referring to FIG. 2, the battery control device 14 of the battery system 10 according to one or more embodiments of the present disclosure may operate in a normal mode (S11), and if a test mode operation is requested by the test device 40 (S12) while the battery system 10 is operating in the normal mode (S11), the battery control device 14 may change the operation mode of the battery system 10 to the test mode (S13).

When operating in the test mode, changes in threshold setting values stored in the storage device 142 may be allowed. If a change in the threshold setting value is requested by the test device 40 (S14), the battery control device 14 may determine whether the change value received from the test device 40 is within a corresponding safety limit range (S15).

If the received change value is within the safety limit range (e.g., YES at S15), the battery control device 14 may change the corresponding threshold setting value to the received change value (S16). If the threshold setting value is changed, the battery control device 14 may control the operation of the protection function of the battery system 10 based on the changed threshold setting value, while the battery system 10 operates in the test mode.

If the received change value is out of the safety limit range (e.g., NO at S15), the battery control device 14 may transmit information notifying that the change value is out of the safety limit range to the test device 40, and may limit the change of the corresponding threshold setting value (S17). For example, the battery control device 14 may maintain the threshold setting value requested for change as the previous value without changing it. In addition, for example, the battery control device 14 may change the threshold setting value requested for change to a value corresponding to the safety limit range.

Thereafter, if the test device 40 is disconnected (e.g., separated) from the battery system 10, or if the test mode is terminated according to a request for termination of the test mode from the test device 40 (S18), the battery control device 14 may change the operation mode of the battery system 10 to the normal mode (S19). The battery control device 14 may also automatically restore the threshold setting value changed during the test mode to the default value before the change as the battery system 10 operates in the normal mode (S20).

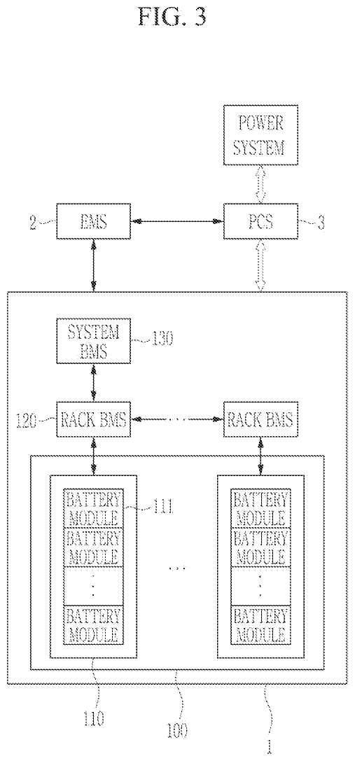

FIG. 3 illustrates an energy storage system (ESS) including a battery system according to an embodiment.

Referring to FIG. 3, the ESS according to an embodiment may include a battery system 1, an energy management system (EMS) 2, and a power conversion system (PCS) 3.

The battery system 1 may include at least one battery bank 100. Each battery bank 100 may include a plurality of battery racks 110 electrically connected to each other in series or in parallel. In addition, each battery rack 110 may include a plurality of battery modules (e.g., a plurality of batteries) 111 electrically connected to each other in series or in parallel. Each battery module 111 may include a plurality of battery cells electrically connected to each other in series or in parallel.

The battery system 1 may include a rack BMS 120 for each corresponding battery rack 110.

The rack BMS 120 may monitor a state of a corresponding battery rack 110 to control the battery system 1 to operate in a desired state (e.g., an optimal state). As such, the rack BMS 120 may perform a state (e.g., a voltage, a current, a temperature, a state of charge (SOC), a state of health (SOH), and/or the like) monitoring function, a control function (e.g., temperature control and cell balancing control), a protection function (e.g., overdischarging, overcharging, overcurrent protection, and the like), and the like for the battery cells configuring the corresponding battery rack 110.

A system BMS 130 may collect data collected by the rack BMS 120 from the rack BMS 120, and may collect and manage the collected data. In addition, if data transmission is requested from the EMS 2, the system BMS 130 may collect and transmit data received from each rack BMS 120 to the EMS 2.

The EMS 2 is an integrated control device that monitors and controls power use of the power system and power supply of the ESS in real time for efficient energy operation of the ESS. The EMS 2 may monitor the state of the entire system (e.g., the battery system 1, the PCS 3, or the like) configuring the ESS, and may control the operation of the ESS.

The PCS 3 may operate as a power conversion device that converts electrical characteristics (e.g., a DC, an AC, a voltage, a frequency, and/or the like) to transmit electrical energy between the battery system 1 and the power system. Generally, electrical energy in the form of DC is used in the battery system 1, and electrical energy in the form of AC is used in the power system. Therefore, the PCS 3 may transmit the electrical energy stored in the battery system 1 to the power system through DC-AC conversion, or may transmit the electrical energy supplied from the power system to the battery system 1 through AC-DC conversion.

In addition to the power conversion and distribution functions described above, the PCS 3 may control an electrical quality, such as active power and reactive power, of the ESS, and may additionally perform a monitoring/control function to monitor the voltage and operation status of the ESS, a grid-connected protection function that protects the power system in case of a power outage, and an independent operation function that operates the ESS by utilizing the battery system 1 even if there is no power.

In the ESS described above, the battery system 1 and the battery module 111 may correspond to the battery system 10 and the battery module 11, respectively, described above with reference to FIG. 1. In addition, the battery control device 14 illustrated in FIG. 1 may be integrated into the rack BMS 120 of the ESS. In addition, the switch 12 and measurement device 13 illustrated in FIG. 1 may be mounted in the battery rack 110.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

### DESCRIPTION OF SYMBOLS

1: battery system
2: EMS
3: PCS
100: battery bank
110: battery rack
111: battery module
120: rack BMS
130: system BMS
10: battery system
11: battery module
12: switch
13: measurement device
14: battery control device
141: communication device
142: storage device
143: controller

What is claimed is:

1. A battery control device of a battery system including at least one battery, comprising:
a storage device configured to store a safety limit range for a parameter related to a state of the at least one battery, and a threshold setting value for the parameter;
a communication device configured to communicate with a test device; and
a controller configured to:
operate a protection function of the battery system based on the threshold setting value;
change the threshold setting value based on a change value received from the test device if a change of the threshold setting value is requested; and
limit the change of the threshold setting value if the change value is out of the safety limit range.

2. The battery control device as claimed in claim 1, wherein to limit the change of the threshold setting value, the controller is configured to maintain the threshold setting value as a previous value if the change value is out of the safety limit range.

3. The battery control device as claimed in claim 1, wherein to limit the change of the threshold setting value, the controller is configured to change the threshold setting value to a value corresponding to the safety limit range if the change value is out of the safety limit range.

4. The battery control device as claimed in claim 1, wherein the controller is further configured to notify the test device that the change value is not a valid value if the change value is out of the safety limit range.

5. The battery control device as claimed in claim 1, wherein the controller is further configured to:
change an operation mode of the battery system to a test mode when requested to enter the test mode by the test device; and
allow the threshold setting value to be changed only while the battery system operates in the test mode.

6. The battery control device as claimed in claim 5, wherein, if the threshold setting value is changed while the battery system operates in the test mode, the controller is further configured to control an operation of the protection function based on the changed threshold setting value.

7. The battery control device as claimed in claim 5, wherein the controller is further configured to change an operation mode of the battery system to a normal mode if connection between the battery system and the test device is disconnected, or if a termination of the test mode is requested by the test device.

8. The battery control device as claimed in claim 7, wherein the controller is further configured to change the threshold setting value to a default value if the operation mode of the battery system is changed to the normal mode, and
wherein the default value is a value outside the safety limit range.

9. The battery control device as claimed in claim 8, wherein the parameter is a cell voltage, a module voltage, a current, or a temperature of the at least one battery, and
wherein the threshold setting value is an overvoltage threshold value, a low voltage threshold value, an overcurrent threshold value, or an overtemperature threshold value of the at least one battery.

10. The battery control device as claimed in claim 9, wherein the threshold setting value is the overvoltage threshold value, and the default value of the overvoltage threshold value is higher than an upper voltage limit of the safety limit range.

11. The battery control device as claimed in claim 9, wherein the threshold setting value is the low voltage threshold value, and the default value of the low voltage threshold value is lower than a lower voltage limit of the safety limit range.

12. The battery control device as claimed in claim 9, wherein the threshold setting value is the overcurrent threshold value, and the default value of the overcurrent threshold value is higher than an upper current limit of the safety limit range.

13. The battery control device as claimed in claim 9, wherein the threshold setting value is the overtemperature threshold value, and the default value of the overtemperature threshold value is higher than an upper temperature limit of the safety limit range.

14. The battery control device as claimed in claim 1, wherein the protection function comprises a function of opening a switch connected between the at least one battery and a load of the battery system.

15. The battery system comprising:
the at least one battery; and
the battery control device according to claim 1.

16. A control method of a battery system including at least one battery, comprising:
receiving a change request for a threshold setting value of a parameter related to a state of the at least one battery;
determining whether or not a change value of the threshold setting value is out of a safety limit range;
if the change value is within the safety limit range, changing the threshold setting value to the change value;
if the change value is out of the safety limit range, limiting a change of the threshold setting value; and
controlling an operation of a protection function of the battery system based on the threshold setting value.

17. The control method as claimed in claim 16, wherein the limiting of the change of the threshold setting value comprises:
maintaining the threshold setting value as a previous value if the change value is out of the safety limit range; or
changing the threshold setting value to a value corresponding to the safety limit range if the change value is out of the safety limit range.

18. The control method as claimed in claim 16, further comprising:
receiving a change request to a test mode; and
changing an operation mode of the battery system to the test mode,
wherein the change of the threshold setting value is allowed only while the battery system operates in the test mode.

19. The control method as claimed in claim 16, further comprising:
changing an operation mode of the battery system to a normal mode if a connection between the battery system and a test device is disconnected, or if termination of a test mode is requested; and
changing the threshold setting value to a default value if the operation mode of the battery system is changed to the normal mode,
wherein the default value is a value outside the safety limit range.

20. The control method as claimed in claim 19, wherein:
the parameter is at least one of a cell voltage, a module voltage, a current, or a temperature of the at least one battery;
the threshold setting value is at least one of an overvoltage threshold value, a low voltage threshold value, an overcurrent threshold value, or an overtemperature threshold value of the at least one battery;
the default value of the overvoltage threshold value is higher than an upper voltage limit of the safety limit range;
the default value of the low voltage threshold value is lower than a lower voltage limit of the safety limit range;
the default value of the overcurrent threshold value is higher than an upper current limit of the safety limit range; and
the default value of the overtemperature threshold value is higher than an upper temperature limit of the safety limit range.
